(19) United States
(12) Patent Application Publication
(10) Pub. No.: US 2013/0106478 A1
(43) Pub. Date: May 2, 2013

(54) CLOCK BUFFER CIRCUIT AND DATA OUTPUT CIRCUIT INCLUDING THE SAME

(71) Applicants: Byong-mo MOON, Seoul (KR); Min-su AHN, Gyeonggi-do (KR)

(72) Inventors: Byong-mo MOON, Seoul (KR); Min-su AHN, Gyeonggi-do (KR)

(73) Assignee: SAMSUNG ELECTRONICS CO., LTD., Suwon-si (KR)

(21) Appl. No.: 13/599,693

(22) Filed: Aug. 30, 2012

(30) Foreign Application Priority Data
Nov. 2, 2011 (KR) 1020110113590

(51) Int. Cl. H03L 7/00

(52) U.S. Cl. 327/161

(57) ABSTRACT

A clock buffer circuit that generates a clock signal having a random cycle and duty from an input clock signal and a data output circuit including the same. The clock buffer circuit includes a buffer unit configured to receive an input clock signal and generate an internal clock signal and a first clock signal; a delay controller configured to receive the internal clock signal from the buffer unit and generate a delayed control signal according to a first control signal and a second control signal; and a delay unit configured to generate a second clock signal according to the first clock signal received from the buffer unit and the second clock signal received from the delay controller. The delay unit is configured to generate the second clock signal by randomly delaying transmission of the first clock signal.

### CROSS-REFERENCE TO RELATED APPLICATIONS

This application claims the benefit of Korean Patent Application No. 10-2011-0113590, filed on Nov. 2, 2011, in the Korean Intellectual Property Office, the disclosure of which is incorporated herein in its entirety by reference.

### BACKGROUND

Example embodiments of the inventive concepts relate to a clock buffer circuit capable of alleviating electromagnetic interference (EMI) and/or a data output circuit including the same.

Recently, as advancements in industries and multimedia have triggered a need to process data at high speeds, the number of semiconductor devices that use high-frequency clock signals have increased accordingly. Thus, more attention has been paid to EMI issues.

EMI means that an electronic product is influenced by electromagnetic waves being emitted from other electronic products that use electrical energy. As the degree of integration and performance of semiconductor devices for use in computers or mobile devices have improved, EMI issues have become much more serious.

### SUMMARY

At least one example embodiment of the inventive concepts provide a clock buffer circuit configured to alleviate electromagnetic interference (EMI) by changing a cycle and a duty of a clock signal by randomly delaying transmission of the clock signal and a data output circuit including the same.

According to an example embodiment of the inventive concept, there is provided a clock buffer circuit including a buffer unit configured to receive an input clock signal and generate an internal clock signal and a first clock signal; a delay controller configured to receive the internal clock signal from the buffer unit and generate a delayed control signal according to a first control signal and a second control signal; and a delay unit configured to generate a second clock signal according to the first clock signal received from the buffer unit and the delayed control signal received from the delay controller. The delay unit is configured to generate the second clock signal by randomly adjusting a propagation delay time of the first clock signal.

The input clock signal may include a pair of clock signals having different phases.

The buffer unit may be configured to generate the internal clock signal and the first clock signal independently with respect to the first and second control signals.

The buffer unit may include a first input buffer configured to receive the input clock signal and generate the internal clock signal; and a second input buffer configured to generate the first clock signal by buffering the internal clock signal.

The delay controller may include a random number generation unit configured to receive the internal clock signal, the first control signal, and the second control signal and generate a pseudo random number by using a linear feedback shift register (LFSR); and an output control logic configured to receive the pseudo random number and output the delayed control signal according to the first control signal.

The random number generation unit may include first to fourth flip flops connected in series; an inverter configured to invert an output of the third flip flop; an XOR gate configured to receive the inverted output of the third flip flop and an output of the fourth flip flop and perform an XOR operation on the inverted output of the third flip flop and the output of the fourth flip flop; a first control logic configured to receive an output of the XOR gate and input the output of the XOR gate to the first flip flop according to the first and second control signals; and a second control logic configured to input the internal clock signal to each of the first to fourth flip flops according to the first and second control signals.

The delay unit may include a first delayer configured to delay the first clock signal; a second delayer configured to delay the first clock signal according to the delayed first clock signal; and a third delayer configured to delay the first clock signal according to the delayed control signal and the first control signal. The first to third delayers may be connected in parallel and one of outputs of the first to third delayers may be randomly output as the second clock signal according to a propagation delay time of each of the first to third delayers.

The delay unit may further include a fourth delayer configured to delay the second clock signal. The fourth delayer may be connected in series to the first to third delayers.

The first delayer and the fourth delayer may delay the first clock signal independently with respect to the delayed control signal and the first control signal.

The second delayer may include a first PMOS transistor connected to a power supply voltage source and turned on according to the delayed control signal inverted by the inverter; a second PMOS transistor connected to the first PMOS transistor; a first NMOS transistor connected to the second PMOS transistor; and a second NMOS transistor connected to the first NMOS transistor, connected to a ground voltage source, and turned on according to the delayed control signal. The inverter may be connected to a gate of the first PMOS transistor, gates of the second PMOS transistor and the first NMOS transistor may be connected and the second PMOS transistor and the first NMOS transistor may be turned on according to the first clock signal.

The third delayer may include a delayer configured to delay the first clock signal; and a third control logic configured to invert the delayed control signal according to the first control signal and outputting the inverted delayed control signal to the delayer.

The delayer may include a third PMOS transistor connected to a power supply voltage source, and turned on according to the delayed control signal inverted by the inverter; a fourth PMOS transistor connected to the third PMOS transistor; a third NMOS transistor connected to the fourth PMOS transistor; and a fourth NMOS transistor connected to the third NMOS transistor, connected to a ground voltage source, and turned on according to the inverted delayed control signal. The inverter may be connected to a gate of the third PMOS transistor, gates of the fourth PMOS transistor and the third NMOS transistor may be connected, and the fourth PMOS transistor and the third NMOS transistor may be turned on according to the first clock signal.

A duty of the second clock signal may be different from those of the input clock signal and the first clock signal.

According to an example embodiment of the inventive concept, there is provided a data output circuit including a clock buffer circuit and an output circuit. The clock buffer includes a buffer unit configured to receive an input clock signal and generating an internal clock signal and a first clock signal; a delay controller configured to receive the internal clock signal from the buffer unit and generating a delayed control signal according to a first control signal and a second control signal; and a delay unit configured to generate a second clock signal according to the first control signal received from the buffer unit and the delayed control signal received from the delay controller. The output circuit outputs data in synchronization with the second clock signal received from the clock buffer circuit. The delay unit generates the second clock signal by randomly delaying transmission of the first clock signal.

A duty of the second clock signal may be different from those of the input clock signal and the first clock signal.

According to an example embodiment, there is provided a clock buffer circuit including a delay unit configured to randomly adjusting a propagation delay time of the first clock signal to generate a second clock signal according to at least one delayed control signal.

The clock buffer circuit may include a delay controller configured to generate the at least one delayed control signal according to at least one control signal.

The delay controller may include a random number generation unit configured to generate a pseudo random number by using a linear feedback shift register (LFSR) according to an internal clock signal and the at least one control signal and configured to output the delayed control signal according the pseudo random number and the at least one control signal.

The random number generation unit may include first to fourth flip flops connected in series; an inverter configured to invert an output of the third flip flop; an XOR gate configured to receive the inverted output of the third flip flop and an output of the fourth flip flop and perform an XOR operation on the inverted output of the third flip flop and the output of the fourth flip flop; a first control logic configured to receive an output of the XOR gate, and input the output of the XOR gate to the first flip flop according to the at least one control signal; and a second control logic configured to input the internal clock signal to each of the first to fourth flip flops according to the at least one control signal.

The delay unit may include a first delayer configured to delay the first clock signal; a second delayer configured to delay the first clock signal according to the delayed first clock signal; and a third delayer configured to delay the first clock signal according to the delayed control signal and the first control signal. The first to third delayers may be connected in parallel, and one of outputs of the first to third delayers may be randomly output as the second clock signal according to a propagation delay time of each of the first to third delayers.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram illustrating an example of a clock buffer circuit according to an example embodiment of the inventive concepts;

FIG. 2 is a detailed block diagram illustrating an example of a buffer unit illustrated in FIG. 1, according to an example embodiment of the inventive concepts;

FIGS. 3A and 3B are diagrams illustrating an example of a delay controller illustrated in FIG. 1, according to some example embodiments of the inventive concepts;

FIGS. 4A to 4E are diagrams illustrating an example of a delay unit illustrated in FIG. 1, according to some example embodiments of the inventive concepts;

FIG. 5 is a graph comparing electromagnetic interference (EMI) characteristics of the clock buffer circuit illustrated in FIG. 1 according to an example embodiment of the inventive concepts with EMI characteristics of a general clock buffer circuit;

FIG. 6 is a block diagram illustrating an example of a data output circuit according to an example embodiment of the inventive concepts;

FIG. 7 is a circuit diagram illustrating an example of a memory device that includes the data output circuit of FIG. 6, according to an example embodiment of the inventive concepts;

FIG. 8 is a block diagram illustrating an example of an electronic system that includes the memory device of FIG. 7, according to an example embodiment of the inventive concepts;

FIG. 9 is a block diagram illustrating an example of a memory system that includes the clock buffer circuit of FIG. 1, according to an example embodiment of the inventive concepts;

FIG. 10 is a block diagram illustrating an example of a computer system that includes the clock buffer circuit of FIG. 1, according to an example embodiment of the inventive concepts; and

FIG. 11 is a block diagram illustrating an example of a data line driver of a display driving circuit that includes the clock buffer circuit of FIG. 1, according to an example embodiment of the inventive concepts.

### DETAILED DESCRIPTION

Hereinafter, example embodiments of the inventive concept will be described more fully with reference to the accompanying drawings. Example embodiments of the inventive concepts may, however, be embodied in many different forms and should not be construed as limited to the example embodiments set forth herein. Rather, these example embodiments are provided so that this disclosure will be thorough and complete, and will fully convey the scope of example embodiments of the inventive concepts to those of ordinary skill in the art. Like reference numerals denote like elements throughout the drawings. In the drawings, the lengths and sizes of layers and regions may be exaggerated for clarity.

The terminology used herein is for the purpose of describing example embodiments only and is not intended to be limiting of the inventive concepts. As used herein, the singular forms ‘a’, ‘an’, and ‘the’ are intended to include the plural forms as well, unless the context clearly indicates otherwise. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “and/or” includes any and all combinations of one or more of the associated listed items. Expressions such as “at least one of,” when preceding a list of elements, modify the entire list of elements and do not modify the individual elements of the list.

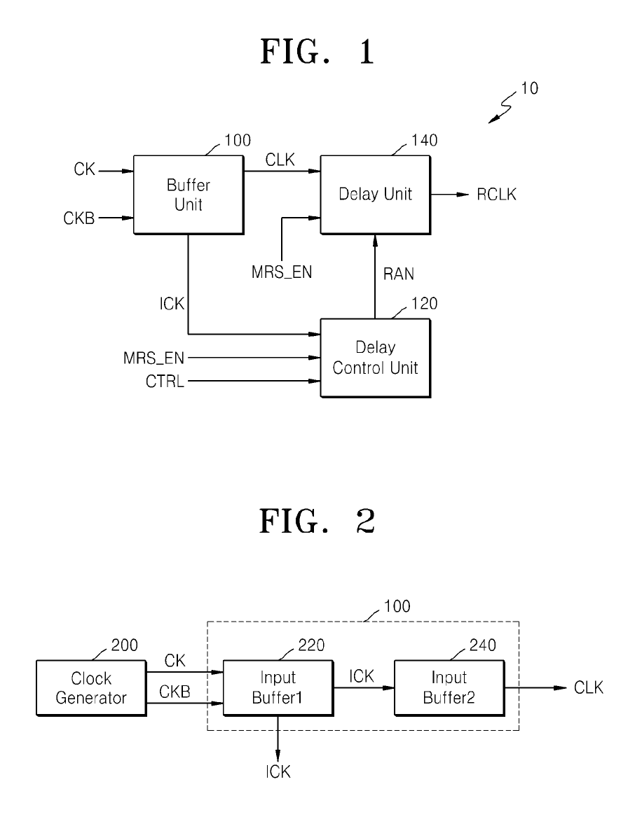

FIG. 1 is a block diagram illustrating an example of a clock buffer circuit 10 according to an example embodiment of the inventive concepts. Referring to FIG. 1, the clock buffer circuit 10 includes a buffer unit 100, a delay controller 120, and a delay unit 140. The buffer unit 100 receives input clock signals CK and CKB and generates an internal clock signal ICK and a first clock signal CLK. The delay controller 120 receives the internal clock signal ICK from the buffer unit 100, and generates a delayed control signal RAN according to a first control signal MRS_EN and a second control signal CTRL. The delay unit 140 generates a second clock signal RCLK by randomly adjusting a propagation delay time of the first clock signal CLK, according to the first clock signal CLK received from the buffer unit 100 and the delayed control signal RAN received from the delay controller 120. Structures of the buffer unit 100, the delay controller 120, and the delay unit 140, and an operation of the clock buffer circuit 10 according to the first control signal MRS_EN and the second control signal CTRL will be described in detail with reference to FIGS. 1 to 4 below.

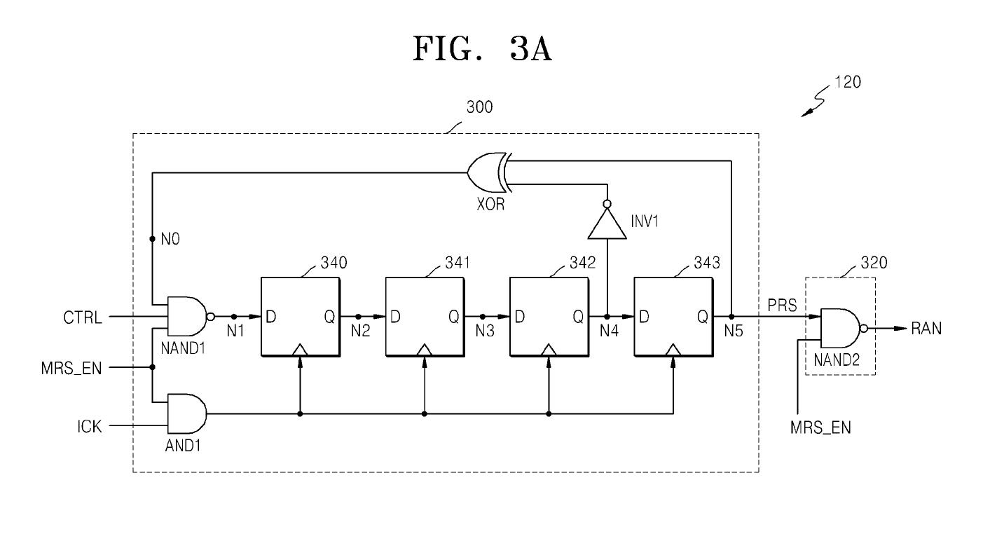

FIG. 2 is a detailed block diagram illustrating an example of the buffer unit 100 of FIG. 1, according to an example embodiment of the inventive concepts. Referring to FIGS. 1 and 2, the buffer unit 100 includes a first input buffer 220 and a second input buffer 240.

The first input buffer 220 receives input clock signals CK and CKB generated by a clock generator 200, and generates an internal clock signal ICK. The clock generator 200 may be a ring oscillator that includes at least one inverter or at least one differential amplifier. The input clock signals CK and CKB have different phases. Although FIGS. 1 and 2 illustrate that the input clock signals CK and CKB having different phases are input to the buffer unit 100, example embodiments of the inventive concepts are not limited thereto and only one clock signal may be input to the buffer unit 100. The first input buffer 220 generates the internal clock signal ICK from the input clock signals CK and CKB. Although not shown, the first input buffer 220 may include a delay-locked loop (DLL) circuit, and may generate the internal clock signal ICK to be synchronized with the input clock signals CK and CKB. The first input buffer 220 may include a duty cycle correction circuit that controls duty cycles of the input clock signals CK and CKB. The first input buffer 220 transmits the internal clock signal ICK to the second input buffer 240 and the delay controller 120.

The second input buffer 240 generates a first clock signal CLK by buffering the internal clock signal ICK. The second input buffer 240 may include at least one inverter. For example, if the second input buffer 240 includes two inverters, the second input buffer 240 may generate the first clock signal CLK having the same phase as the input clock signal CK by delaying the internal clock signal ICK.

The buffer unit 100 operates independently with respect to the first control signal MRS_EN and the second control signal CTRL. Thus, the buffer unit 100 may operate even if the first control signal MRS_EN and the second control signal CTRL disable the delay controller 120 and the delay unit 140, as will be described in detail below.

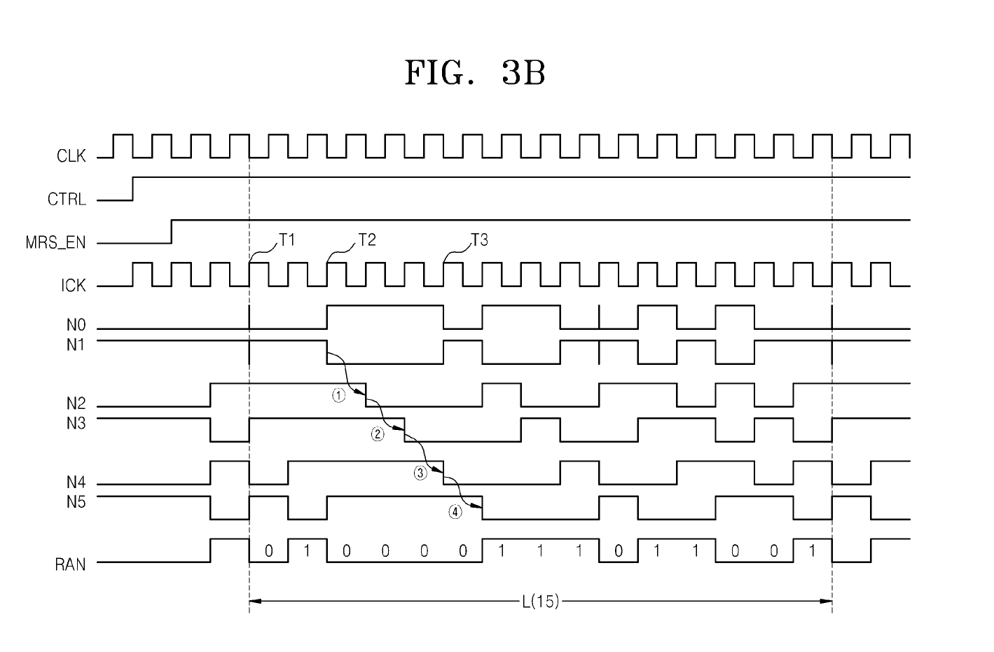

FIGS. 3A and 3B are diagrams illustrating the delay controller 120 of FIG. 1. FIG. 3A is a circuit diagram illustrating an example of the delay controller 120 according to an example embodiment of the inventive concepts, and FIG. 3B is a waveform diagram illustrating an example of signals at nodes connecting elements of the delay controller 120, according to an example embodiment of the inventive concepts.

Referring to FIGS. 1 and 3A, the delay controller 120 includes a random number generation unit 300 controlled using a first control signal MRS_EN and a second control signal CTRL, and an output control logic 320 controlled using the first control signal MRS_EN.

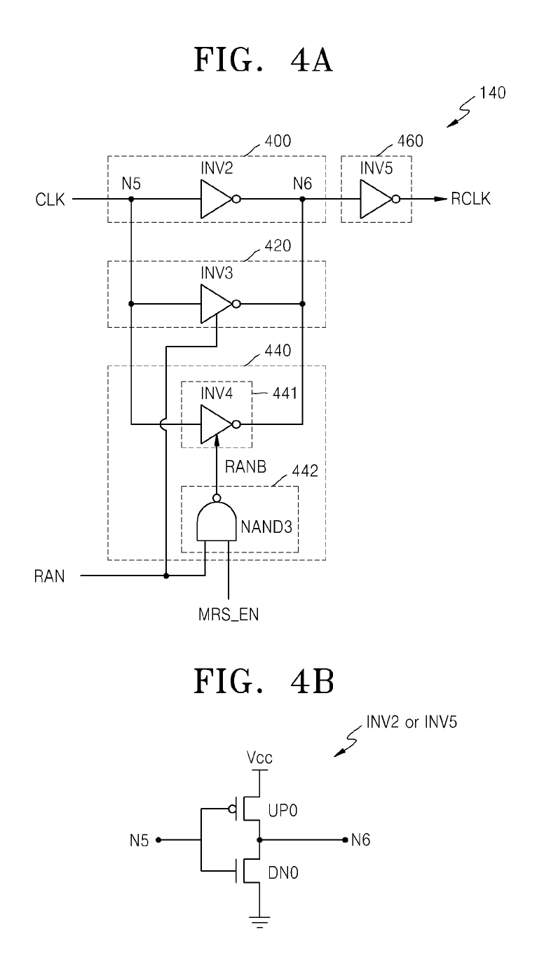

The first control signal MRS_EN turns on/off the delay controller 120. The first control signal MRS_EN may be a set mode register setting signal if a semiconductor device (not shown) that includes the clock buffer circuit 10 is synchronous dynamic random access memory (SDRAM). The first control signal MRS_EN turns on/off the delay controller 120 and a second delayer 420 and a third delayer 440 included in the delay unit 140 (see FIG. 4A). Thus, if a cycle and a duty of a first clock signal CLK does not need to be adjusted using a delayed control signal RAN, the delay controller 120 and the second delayer 420 and the third delayer 440 included in the delay unit 140 are turned off to prevent unnecessary power consumption, as will be described in detail below.

The second control signal CTRL turns on/off the random number generation unit 300 included in the delay controller 120. To prevent unnecessary power consumption, the second control signal CTRL may be set to control the random number generation unit 300 to be turned on/off according to a driving operation of the semiconductor device including the clock buffer circuit 10. For example, if the semiconductor device is SDRAM, the second control signal CTRL may be set to turn on the random number generation unit 300 only during a read operation. The second control signal CTRL may be set to turn on the random number generation unit 300 only during a write operation or only during both the write operation and the read operation.

The random number generation unit 300 generates a pseudo random number sequence (PRS) to be synchronized with an internal clock signal ICK. The random number generation unit 300 may be embodied using a linear feedback shift register (LFSR). The LFSR may be manufactured using n shift registers, for example, n flip flops, and an XOR gate. The LFSR may generate a PRS in a cycle of L(2ⁿ⁻¹). For example, the random number generation unit 300 may include a first NAND gate NAND1, a first AND gate AND1, first to fourth flip flops 340, 341, 342 and 343 that are connected in series, a first inverter INV1 and an XOR gate XOR. Although FIG. 3A illustrates that the first to fourth flip flops 340, 341, 342 and 343 are D type flip flops, example embodiments of the inventive concept are not limited thereto and the first to fourth flip flops 340, 341, 342 and 343 may include various types of flip flops. The random number generation unit 300 may include more than four flip flops to generate a PRS in a cycle that is longer than the cycle of L(2ⁿ⁻¹), and flip flops, the output terminals of which are connected to the first inverter INV1 and the XOR gate XOR, may be arbitrarily selected, thereby increasing randomness of the PRS.

The first NAND gate NAND1 outputs an output signal of the XOR gate XOR to the first flip flop 340 if the first control signal MRS_EN and the second control signal CTRL received from the outside are activated, for example, if the first control signal MRS_EN and the second control signal CTRL are logic high.

The first AND gate AND1 inputs the internal clock signal ICK to the first to fourth flip flops 340, 341, 342, and 343 if the first control signal MRS_EN is activated, for example, if the first control signal MRS_EN is logic high.

The first flip flop 340 receives and latches an output signal of the XOR gate XOR that is input to an input terminal D in synchronization with the internal clock signal ICK received from the first AND gate AND1. The first flip flop 340 outputs the latched signal to the second flip flop 341 via an output terminal Q.

The second flip flop 341 receives the output signal of the first flip flop 340 via an input terminal D and latches the output signal in synchronization with the internal clock signal ICK received from the first AND gate AND1. The second flip flop 341 outputs the latched signal to the third flip flop 342 via an output terminal Q.

The third flip flop 342 receives the output signal of the second flip flop 341 via an input terminal D and latches the output signal in synchronization with the internal clock signal ICK received from the first AND gate AND1. The third flip flop 342 outputs the latched signal to the fourth flip flop 343 and the first inverter INV1 that connects the third flip flop 342 and the XOR gate XOR, via an output terminal Q.

The fourth flip flop 343 receives and latches the output signal of the third flip flop 342 that is input to an input terminal D in synchronization with the internal clock signal ICK received from the first AND gate AND1. The fourth flip flop 343 outputs the latched signal to the XOR gate XOR and the output control logic 320, via an output terminal Q.

The XOR gate XOR receives the inverted output signal of the third flip flop 342, which is inverted by the first inverter INV1, and the output signal of the fourth flip flop 343, performs an XOR operation and then outputs the result of performing the XOR operation to the first NAND gate NAND1.

The output control logic 320 may output a delayed control signal RAN according to the first control signal MRS_EN and may include a second NAND gate NAND2. The output control logic 320 receives a PRS in which a bit ‘0’ or ‘1’ is randomly arranged, from the fourth flip flop 343, in a cycle of L. If the first control signal MRS_EN is activated, for example, if the first control signal MRS_EN is logic high, the output control logic 320 inverts the PRS and outputs the delayed control signal RAN to the delay unit 140.

A waveform diagram of signals at nodes that connect elements of the delay controller 120 will now be described above with reference to FIGS. 1, 3A, and 3B.

A node N0 is disposed between the XOR gate XOR and the first NAND gate NAND1. A node N1 is disposed between the first NAND gate NAND1 and the first flip flop 340. A node N2 is disposed between the first flip flop 340 and the second flip flop 341. A node N3 is disposed between the second flip flop 341 and the third flip flop 342. A node N4 connects the third flip flop 342, the first inverter INV1, and the fourth flip flop 343 to one another. A node N5 connects the fourth flip flop 343, the XOR gate XOR, and the output control logic 320 to another. It is assumed that the activating of each signal means that each signal is logic high.

If the first control signal MRS_EN and the second control signal CTRL are logic high, an output signal of the XOR gate XOR is inverted and input to the first flip flop 340 at a rising edge T1 of the internal clock signal ICK (node N0). An output signal of the first flip flop 340 is sequentially input to the second to fourth flip flops 341, 342, and 343 to be sequentially delayed by one cycle. It is noted from a waveform diagram of the output signal of the first NAND gate NAND1 at the node N1 that the output signal of the first NAND gate NAND1 that is logic low at a rising edge T2 of the internal clock signal ICK and that is logic high at a rising edge T3 of the internal clock signal ICK is sequentially delayed by one cycle, as indicated by \textcircled{1} to \textcircled{4} in FIG. 3B (nodes N1 to N5). Thus, a PRS, a cycle L of which is 15 (one cycle=2ⁿ⁻¹, n=4) is output to the output control logic 320 and the XOR gate XOR (node N5). A phase of the delayed control signal RAN is inverted via the output control logic 320 to be opposite to a phase of the output signal, for example the PRS, at the node N5 and is then output to the delay unit 140. The delayed control signal RAN may consist of bits 0, 1, 0, 0, 0, 0, 1, 1, 1, 0, 1, 1, 0, 0, and 1, and the second delayer 420 and the third delayer 440 included in the delay unit 140 are controlled according to a logic level of the delayed control signal RAN.

FIGS. 4A to 4E are diagrams illustrating an example of the delay unit 140 of FIG. 1, according to some example embodiments of the inventive concepts. Referring to FIG. 1 and FIG. 4A that illustrate the delay unit 140 according to an example embodiment of the inventive concepts, the delay unit 140 includes a first delayer 400, the second delayer 420, and the third delayer 440 that are connected in parallel to a node N5 and a node N6. The delay unit 140 may further include a fourth delayer 460 connected in series to the node N6. The first delayer 400, the second delayer 420, and the third delayer 440 may have different propagation delay times. Thus, if a first clock signal CLK is input to the delay unit 140, an output of a delayer having a shortest propagation delay time from among the first delayer 400, the second delayer 420, and the third delayer 440 may be output to the node N6. If the delay unit 140 further includes the fourth delayer 460, the delayer having the shortest propagation delay time may be output as a second clock signal RCLK via the fourth delayer 460.

The first delayer 400 delays the first clock signal CLK. Referring to FIG. 4A and FIG. 4B that illustrates an example of the first delayer 400 according to an example embodiment of the inventive concepts, the first delayer 400 may include a second CMOS inverter INV2 in which a PMOS transistor UP0 connected to a power supply voltage Vcc source and an NMOS transistor DN0 connected to a ground voltage source are connected in series. The first delayer 400 delays the first clock signal CLK independently with respect to a delayed control signal RAN and a first control signal MRS_EN. If the first clock signal CLK is input to the first delayer 400, the first delayer 400 inverts the first clock signal CLK and outputs a second clock signal RCLK. Since the first delayer 400 operates independently with respect to the first control signal MRS_EN, the first delayer 400 may perform buffering in synchronization with an input clock signal together with the buffer unit 100 of FIG. 1, even if the delay controller 120 and the second delayer 420 and the third delayer 440 included in the delay unit 140 are deactivated according to the first control signal MRS_EN.

The second delayer 420 delays the first clock signal CLK in response to the delayed control signal RAN. Referring to FIG. 4A and FIG. 4C that illustrate an example of the second delayer 420 according to an example embodiment of the inventive concepts, the second delayer 420 may include a third inverter INV3. The third inverter INV3 may include a PMOS transistor UP1 connected to a power supply voltage Vcc source; an inverter Inv that is connected to a gate of the PMOS transistor UP1, inverts a delayed control signal RAN, and outputs a result of the inverting to the gate of the PMOS transistor UP1; a PMOS transistor UP2 connected in series to the PMOS transistor UP1; an NMOS transistor DN1 that is connected in series to the PMOS transistor UP2 and the gate of which is connected to a node N5 to which a gate of which the PMOS transistor UP2 is connected; and an NMOS transistor DN2 that is connected in series to the NMOS transistor DN1 and is connected to a ground voltage source. The second delayer 420 may have a different propagation delay time than that of the first delayer 400, since the PMOS transistor UP1 is turned on/off according to the result of inverting the delayed control signal RAN, performed by the inverter Inv, and the NMOS transistor DN2 is turned on/off according to the delayed control signal RAN. The inverter INV3 is turned on/off according to a logic level of the delayed control signal RAN, and the first clock signal CLK input to the node N5 may be randomly inverted.

The third delayer 440 delays the first clock signal CLK according to the delayed control signal RAN and the first control signal MRS_EN. Referring to FIG. 4A and FIG. 4D that illustrates an example of the third delayer 440 according to an example embodiment of the inventive concepts, the third delayer 440 may include a delayer 441 and a third control logic 442. The third control logic 442 may include a third NAND gate NAND3, and inverts the delayed control signal RAN and outputs an inverted delayed control signal RANB to the delayer 441, according to the first control signal MRS_EN. The delayer 441 delays the first clock signal CLK according to the inverted delayed control signal RANB. The delayer 441 may include a fourth inverter INV4. The fourth inverter INV4 that constitutes the delayer 441 may have the same structure as the third inverter INV3 that constitutes the second delayer 420. However, in the fourth inverter INV4, the inverted delayed control signal RANB output from the third NAND gate NAND3 is inverted again by the inverter Inv and is then input to the PMOS transistor UP3, but is directly input to the NMOS transistor DN4, thereby controlling turning on/off of the PMOS transistor UP3 and the NMOS transistor DN4. Thus, the third delayer 440 may have a different propagation delay time than those of the first delayer 400 and the second delayer 420. Since the fourth inverter INV4 is turned on/off according to a logic level of the inverted delayed control signal RANB, inverting of the first clock signal CLK input to the node N5 may be performed differently from inverting performed by the inverter INV3 included in the second delayer 420.

As described above, the delay unit 140 may randomly delay the first clock signal CLK through the first to third delayers 400, 420, and 440 that have different propagation delay times by using the delayed control signal RAN or the inverted delayed control signal RANB. Thus, the delay unit 140 may generate the second clock signal RCLK having a random cycle and duty from the first clock signal CLK.

FIG. 4E is a waveform diagram of signals input to or output from the delay unit 140 of FIG. 4A. Referring to FIG. 4E, a first clock signal CLK may have a regular duty and cycle, whereas a second clock signal RCLK may have a variable cycle and duty. For example, a duty of the second clock signal RCLK, marked with \textcircled{5} is smaller than a corresponding duty of the first clock signal CLK, a duty of the second clock signal RCLK, marked with \textcircled{6} is larger than a corresponding duty of the first clock signal CLK, and a duty of the second clock signal RCLK, marked with \textcircled{7} is equal to a corresponding duty of the first clock signal CLK. The cycle and duty of the second clock signal RCLK may be randomly varied.

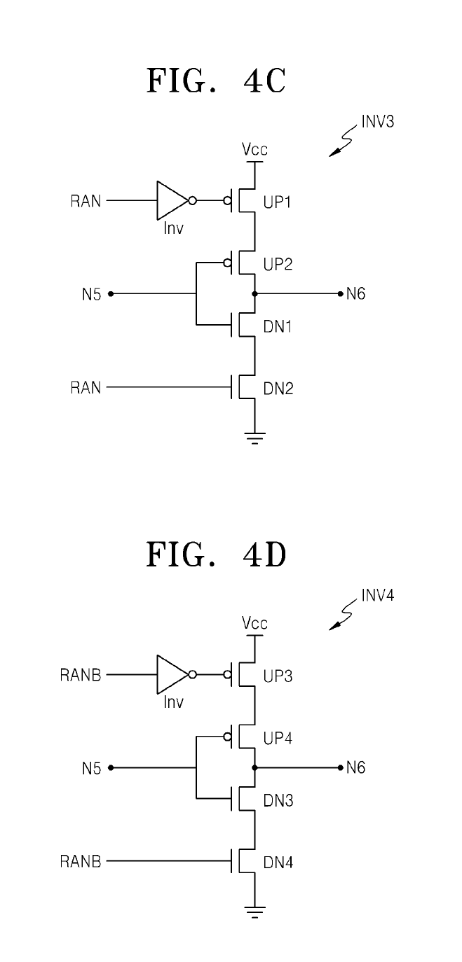

FIG. 5 is a graph comparing electromagnetic interference (EMI) characteristics of the clock buffer circuit 10 illustrated in FIG. 1 according to an example embodiment of the inventive concepts with EMI characteristics of a general clock buffer circuit. Referring to FIG. 5, a graph A marked with a solid line denotes the EMI characteristics of an output (current or voltage) of a semiconductor device (not shown) driven in synchronization with a second clock signal RCLK generated by the clock buffer circuit 10, and a graph B marked with a dotted line denotes an output (current or voltage) of the semiconductor device driven in synchronization with a clock signal generated by the general clock buffer circuit. It is noted from the graph B that a peak value is high at a harmonic frequency component and thus high-energy EMI occurs, whereas it is noted from the graph A that a peak value is low at the harmonic frequency component and energy may be dispersed to another frequency component, thereby reducing EMI. Thus, it is possible to effectively alleviate EMI in the semiconductor device if the second clock signal RCLK generated by the clock buffer circuit 10 is used.

As described above, in the clock buffer circuit 10, whether the delay controller 120 and the second and third delayers 420 and 440 included in the delay unit 140 are to be activated may be determined according to the first control signal MRS_EN, and whether the random number generation unit 300 included in the delay controller 120 is to be activated may be determined according to the second control signal CTRL. The second control signal CTRL may be set to control the random number generation unit 300 to be activated or deactivated according to an operation of a semiconductor device (not shown) that includes the clock buffer circuit 10. The clock buffer circuit 10 may alleviate EMI by activating the delay controller 120 and the second and third delayers 420 and 440 included in the delay unit 140, for example, during a read mode that is greatly influenced by EMI and may reduce power consumption in an operation mode that is less influenced by EMI by deactivating the delay controller 120 and the second and third delayers 420 and 440, from among operation modes of the semiconductor device that includes the clock buffer circuit 10. Since the buffer unit 100 and the fourth delayer 400 of the delay unit 140 first control signal MRS_EN are driven independently with respect to the second control signal CTRL, the semiconductor device may operate in synchronization with an external clock signal even if an operation mode of the semiconductor device including the clock buffer circuit 10 is not influenced by EMI.

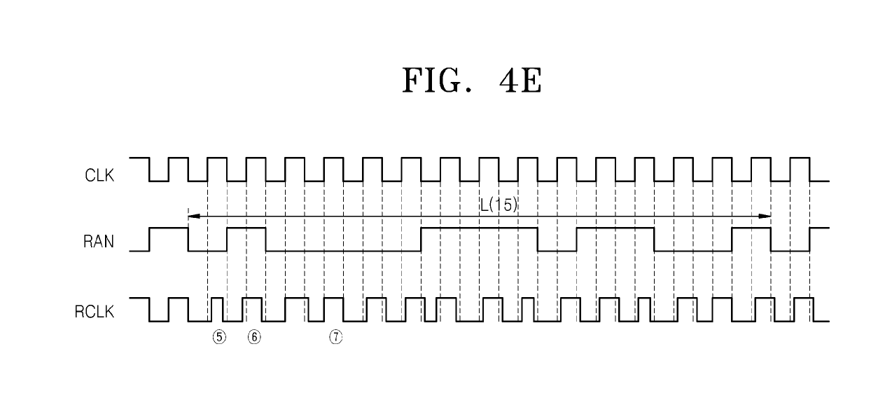

FIG. 6 is a block diagram illustrating an example of a data output circuit 20 according to an example embodiment of the inventive concepts. Referring to FIG. 6, the data output circuit 20 includes a clock buffer circuit 10 and an output circuit 500. The clock buffer circuit 10 receives an input clock signal CK, a first control signal MRS_EN and a second control signal CTRL, and outputs a second clock signal RCLK. The output circuit 500 receives the second clock signal RCLK and outputs external DATA to be synchronized with the second clock signal RCLK.

The clock buffer circuit 10 is substantially the same as the clock buffer circuit 10 illustrated in FIG. 1. Thus, the clock buffer circuit 10 may include the buffer unit 100, the delay controller 120, and the delay unit 140 illustrated in FIG. 1, and may generate the second clock signal RCLK having an irregular cycle and duty (from the input clock signal CK.

The output circuit 500 may include at least one inverter. The output circuit 500 outputs the external data DATA to be synchronized with the second clock signal RCLK. Thus, data DQ output from the output circuit 500 has an irregular cycle and duty.

As described above, in a semiconductor device that includes the data output circuit 20, a cycle and duty of an output signal is irregular and a peak value at a harmonic frequency component may thus be low. Thus, it is possible to effectively alleviate EMI in the semiconductor device, caused when data is processed to be synchronized with a clock signal having a regular cycle and duty.

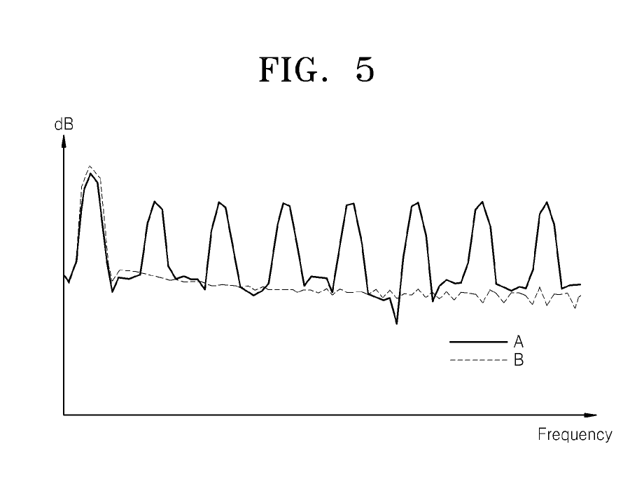

The data output circuit 20 of FIG. 6 according to the example embodiment may be included in a memory device 30 as illustrated in FIG. 7. FIG. 7 is a circuit diagram illustrating an example of some elements of the memory device 30 that may be, for example, double data rate (DDR)-SDRAM, according to an example embodiment of the inventive concepts. Referring to FIG. 7, the memory device 30 may include a memory cell array 600 that includes DRAM cells, and a data output circuit 20 that reduces EMI when data is output from the memory device 30. For convenience of explanation, FIG. 7 does not illustrate various circuit blocks for driving the DRAM cells, for example, a timing register, an address register, a row decoder, a sense amplifier, and the like.

The data output circuit 20 may generate a second clock signal RCLK having an irregular cycle and duty by randomly delaying an input clock signal CK received from a clock generator (not shown) included in the memory device 30, according to a first control signal MRS_EN and a second control signal CTRL, and may output data DATA read from the memory cell array 600 to be synchronized with the second clock signal RCLK. Thus, the cycle and duty of output data DQ may become irregular, thereby alleviating EMI when the output data DQ is output from the memory device 30.

Although FIG. 7 illustrates that the second clock signal RCLK is used when data is output from the memory device 30, example embodiments of the inventive concept are not limited thereto and the second clock signal RCLK may be used if a peak value of an output voltage or current is high at a harmonic frequency component in, for example, the sense amplifier for inputting data to or outputting data from the memory cell array 600, and EMI issues become serious. The clock buffer circuit 10 may provide the second clock signal RCLK to various circuit blocks of the memory device 30. Thus, the clock buffer circuit 10 illustrated as being included in the data output circuit 20 may be arbitrarily arranged in consideration of layout plan of the circuit blocks.

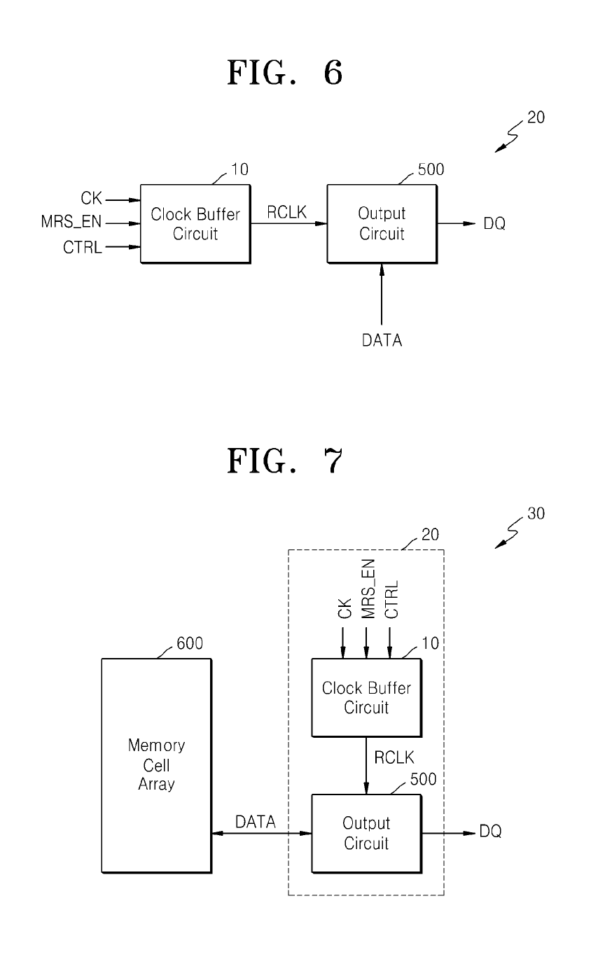

FIG. 8 is a block diagram illustrating an example of an electronic system 40 that includes the memory device 30 of FIG. 7, according to an example embodiment of the inventive concepts. Referring to FIG. 8, the electronic system 40 includes an input device 710, an output device 720, a processor device 730, and a memory device 740. The processor device 730 may control the input device 710, the output device 720, and the memory device 740 via a corresponding interface. The processor device 730 may include at least one from among at least one microprocessor, a digital signal processor, a microcontroller, and logic devices capable of performing operations similar to those of the at least one microprocessor, the digital signal processor, and the microcontroller. The input device 710 and the output device 720 may include at least one selected from among a keypad, a keyboard, and a display device.

The memory device 740 may include the memory device 30, such as a volatile memory device, for example, DDR-SDRAM, or a non-volatile memory device, for example, flash memory. The memory device 740 may include the clock buffer circuit 10 of FIG. 1 or the data output circuit 20 of FIG. 7 that includes the clock buffer circuit 10. Thus, in the memory device 740, a cycle and duty of output data becomes irregular, thereby alleviating EMI that occurs when the output data is output from the memory device 740.

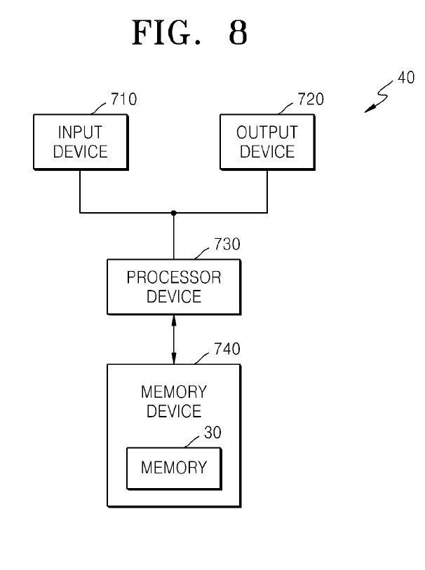

FIG. 9 is a block diagram illustrating an example of a memory system 50 that includes the clock buffer circuit 10 of FIG. 1, according to an example embodiment of the inventive concepts. Referring to FIG. 8, the memory system 50 may include an interface unit 810, a controller 820, and the memory device 840. The interface unit 810 may provide an interface between the memory system 50 and a host (not shown). The interface unit 810 may include a data exchange protocol corresponding to the host to interface with the host. The interface unit 810 may be constructed to communicate with the host by using one of various interface protocols, such as a universal serial bus (USB), a multi-media card (MMC), a peripheral component interconnect-express (PCI-E), a small computer system interface (SCSI), a serial-attached SCSI (SAS), a serial advanced technology attachment (SATA), a parallel advanced technology attachment (PATA), an enhanced small disk interface (ESDI) and integrated drive electronics (IDE).

The controller 820 may receive data and an address from the outside via the interface unit 810. The controller 820 may access the memory device 840 based on data and an address received from the host. The controller 820 may provide the host with data read from the memory device 840 via the interface unit 810.

The controller 820 may include a buffer memory 821. The buffer memory 821 temporarily stores write data received from the host or data read from the memory device 840. If data present in the memory device 840 is cached if a request to perform a read command is received from the host, the buffer memory 821 supports a cache function of directly providing the cached data to the host. In general, a data transmission speed according to a bus format of the host, for example, a SATA or a SAS, may be much faster than that of a memory channel in the memory system 50. If an interfacing speed of the host is much faster than that of the memory channel, the buffer memory 821 may be used to minimize degradation in the performance of the memory system 50 caused by this speed difference.

The memory device 840 may be provided as a storage medium of the memory system 50. For example, the memory device 840 may be embodied as a resistive memory device or may be embodied as a NAND-type flash memory having a large storage capacity. The memory device 840 may include a plurality of memory devices (not shown). The memory device 840 as a storage medium may be phase change RAM (PRAM), magnetic RAM (MRAM), resistive RAM (ReRAM), ferroelectric RAM (FRAM), NOR flash memory, or the like. The memory system 50 may include different types of memory devices. The memory device 840 may include a volatile memory device, for example, DDR-SDRAM. The memory device 840 may include the clock buffer circuit 10 of FIG. 1 or the data output circuit 20 of FIG. 6 that includes the clock buffer circuit 10. Thus, in the memory device 840, a cycle and duty of output data becomes irregular, thereby reducing EMI when the output data is output.

The memory system 50 of FIG. 9 may be installed in information processors, such as a personal digital assistant (PDA), a mobile computer, a web tablet, a digital camera, a portable media player (PMP), a mobile phone, a wireless phone, and a lap-top computer. The memory system 50 may be embodied as an MMC, a secure digital (SD) card, a micro SD card, a memory stick, an identification (ID) card, a personal computer memory card international association (PCMCIA) card, a chip card, a USB card, a smart card, or a compact flash (CF) card.

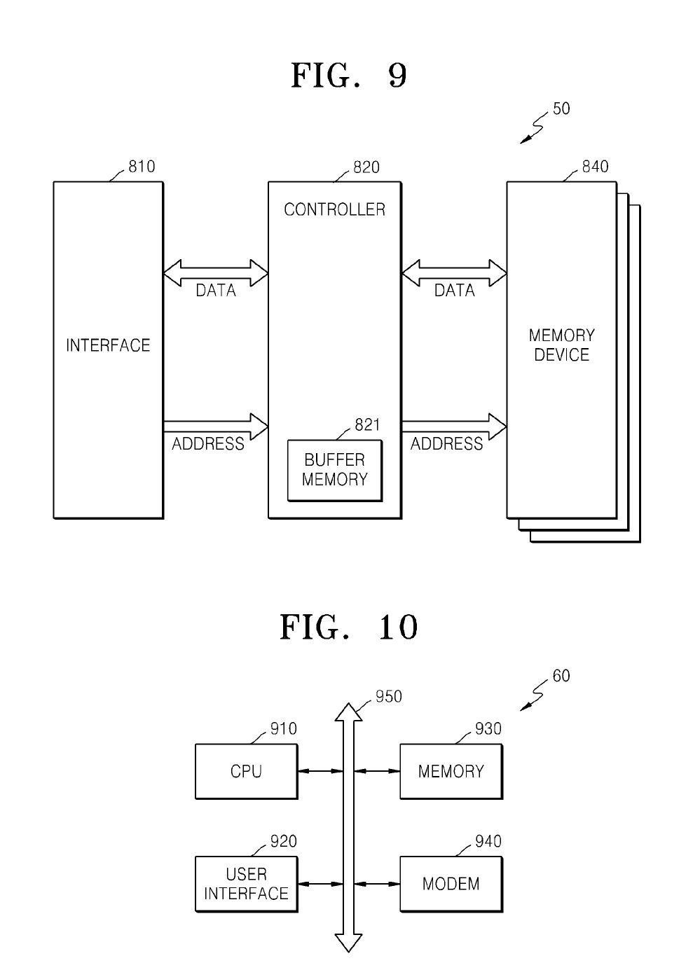

FIG. 10 is a block diagram illustrating an example of a computer system 60 that includes the clock buffer circuit 10 of FIG. 1, according to an example embodiment of the inventive concepts. Referring to FIG. 10, the computer system 60 may include a central processing unit (CPU) 910, a user interface 920, a memory 930, and a modem 940, such as a baseband chipset, which are electrically connected to a system bus 950. The user interface 920 may be an interface for transmitting data or receiving data in a communication network. The user interface 920 may be a wired/wireless interface and may include an antenna or a wired/wireless transceiver. Data that is provided via the user interface 920 or the modem 940 or that is processed by the CPU 910 may be stored in the memory 930.

The memory 930 may include a volatile memory device, for example, DRAM, and/or a non-volatile memory device, for example, flash memory. The memory 930 may be DRAM, PRAM, MRAM, ReRAM, FRAM, NOR flash memory, NAND flash memory, or fusion flash memory, for example, a combination of an SRAM buffer, NAND flash memory, and a NOR interface logic unit, in which the clock buffer circuit 10 of FIG. 1 or the data output circuit 20 of FIG. 6 that includes the clock buffer circuit 10 is installed.

If the computer system 60 is a mobile device, a battery (not shown) may be additionally provided to apply an operating voltage to the computer system 60. Although not shown, the computer system 60 may further include an application chipset, a camera image processor (CIP), an input/output (I/O) device, and the like.

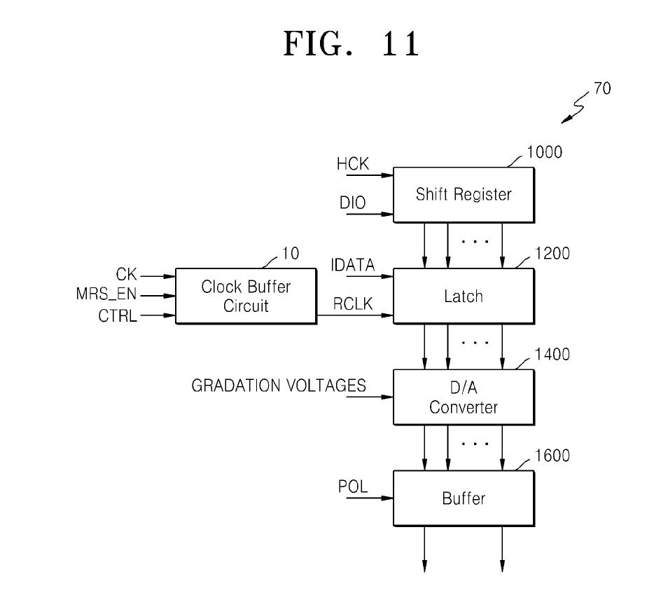

FIG. 11 is a block diagram illustrating an example of a data line driver 70 of a display driving circuit (not shown) that includes the clock buffer circuit 10 of FIG. 1, according to an example embodiment of the inventive concepts. The data line driver 70 is an example of a data line driver (or a source driver) for driving a flat panel display. The data line driver 70 may be a driver for driving small or medium -sized display devices, such as a mobile phone and a PDA, or large-sized display devices, such as a liquid crystal display (LCD) monitor and an LCD TV.

The data line driver 70 includes a clock buffer circuit 10, a shift register 1000, a latch 1200, a digital-to-analog (D/A) converter 1400, and a buffer 1600. The clock buffer circuit 10 generates a second clock signal RCLK, based on an input clock signal CK, a first control signal MRS_EN, and a second control signal CTRL, as described above with reference to FIGS. 1 to 5.

The shift register 1000 includes a plurality of registers (not shown) that are connected in series, and the plurality of registers sequentially shift a horizontal start signal DI0 received from a timing controller (not shown) according to a horizontal clock signal HCLK received from the timing controller. The horizontal start signal DM functions as a start pulse signal indicating start of an operation.

The latch 1200 includes a plurality of latches, stores digital data IDATA input based on an output signal of the shift register 1000 and outputs the stored digital data IDATA in synchronization with the second clock signal RCLK received from the clock buffer circuit 10.

The D/A converter 1400 selects a gradation voltage from among gradation voltages input based on the digital data IDATA output from the latch 1200 and outputs analog voltages corresponding to the digital data IDATA output from the latch 1200.

The buffer 1600 includes a plurality of buffers, buffers the analog voltages output from the D/A converter 1400 and provides the analog voltages output to data lines of a display panel (not shown) according to a polarity control signal POL.

When data is output from the display driving circuit, the clock buffer circuit 10 may be used to effectively alleviate EMI caused when data is processed in synchronization with a clock signal.

While example embodiments of the inventive concept have been particularly shown and described with reference to some example embodiments, it will be understood that various changes in form and details may be made therein without departing from the spirit and scope of the following claims.

What is claimed is:

1. A clock buffer circuit comprising:
a buffer unit configured to receive an input clock signal and generate an internal clock signal and a first clock signal;
a delay controller configured to receive the internal clock signal from the buffer unit and generate a delayed control signal according to a first control signal and a second control signal; and
a delay unit configured to generate a second clock signal according to the first clock signal received from the buffer unit and the delayed control signal received from the delay controller,
wherein the delay unit is configured to generate the second clock signal by randomly adjusting a propagation delay time of the first clock signal.

2. The clock buffer circuit of claim 1, wherein the input clock signal includes a pair of clock signals having different phases.

3. The clock buffer circuit of claim 1, wherein the buffer unit is configured to generate the internal clock signal and the first clock signal independently with respect to the first and second control signals.

4. The clock buffer circuit of claim 1, wherein the buffer unit comprises:
a first input buffer configured to receive the input clock signal and generate the internal clock signal; and
a second input buffer configured to generate the first clock signal by buffering the internal clock signal.

5. The clock buffer circuit of claim 1, wherein the delay controller comprises:
a random number generation unit configured to receive the internal clock signal, the first control signal and the second control signal and generate a pseudo random number by using a linear feedback shift register (LFSR); and
an output control logic configured to receive the pseudo random number and output the delayed control signal according to the first control signal.

6. The clock buffer circuit of claim 5, wherein the random number generation unit comprises:
first to fourth flip flops connected in series;
an inverter configured to invert an output of the third flip flop;
an XOR gate configured to receive the inverted output of the third flip flop and an output of the fourth flip flop and perform an XOR operation on the inverted output of the third flip flop and the output of the fourth flip flop;
a first control logic configured to receive an output of the XOR gate and input the output of the XOR gate to the first flip flop according to the first and second control signals; and
a second control logic configured to input the internal clock signal to each of the first to fourth flip flops according to the first and second control signals.

7. The clock buffer circuit of claim 1, wherein the delay unit comprises:
a first delayer configured to delay the first clock signal;
a second delayer configured to delay the first clock signal according to the delayed first clock signal; and
a third delayer for delaying the first clock signal according to the delayed control signal and the first control signal,
wherein the first to third delayers are connected in parallel, and
one of outputs of the first to third delayers is randomly output as the second clock signal according to a propagation delay time of each of the first to third delayers.

8. The clock buffer circuit of claim 7, wherein the delay unit further comprises a fourth delayer for delaying the second clock signal,
wherein the fourth delayer is connected in series to the first to third delayers.

9. The clock buffer circuit of claim 7, wherein the first delayer and the fourth delayer delay the first clock signal independently with respect to the delayed control signal and the first control signal.

10. The clock buffer circuit of claim 7, wherein the second delayer comprises:
a first PMOS transistor connected to a power supply voltage source and turned on according to the delayed control signal inverted by the inverter;
a second PMOS transistor connected to the first PMOS transistor;
a first NMOS transistor connected to the second PMOS transistor; and
a second NMOS transistor connected to the first NMOS transistor, connected to a ground voltage source and turned on according to the delayed control signal,
wherein the inverter is connected to a gate of the first PMOS transistor,
gates of the second PMOS transistor and the first NMOS transistor are connected, and
the second PMOS transistor and the first NMOS transistor are turned on according to the first clock signal.

11. The clock buffer circuit of claim 7, wherein the third delayer comprises:
a delayer configured to delay the first clock signal; and
a third control logic configured to invert the delayed control signal according to the first control signal and output the inverted delayed control signal to the delayer.

12. The clock buffer circuit of claim 11, wherein the delayer comprises:
a third PMOS transistor connected to a power supply voltage source and turned on according to the delayed control signal inverted by the inverter;
a fourth PMOS transistor connected to the third PMOS transistor;
a third NMOS transistor connected to the fourth PMOS transistor; and
a fourth NMOS transistor connected to the third NMOS transistor, connected to a ground voltage source and turned on according to the inverted delayed control signal,
wherein the inverter is connected to a gate of the third PMOS transistor,
gates of the fourth PMOS transistor and the third NMOS transistor are connected, and
the fourth PMOS transistor and the third NMOS transistor are turned on according to the first clock signal.

13. The clock buffer circuit of claim 1, wherein a duty of the second clock signal is different from those of the input clock signal and the first clock signal.

14. A data output circuit comprising:
a clock buffer circuit including,
a buffer unit configured to receive an input clock signal and generate an internal clock signal and a first clock signal;
a delay controller configured to receive the internal clock signal from the buffer unit and generate a delayed control signal according to a first control signal and a second control signal; and
a delay unit configured to generate a second clock signal according to the first control signal received from the buffer unit and the delayed control signal received from the delay controller; and
an output circuit configured to output data in synchronization with the second clock signal received from the clock buffer circuit,
wherein the delay unit is configured to generate the second clock signal by randomly delaying transmission of the first clock signal.

15. The data output circuit of claim 14, wherein a duty of the second clock signal is different from those of the input clock signal and the first clock signal.

16. A clock buffer circuit comprising:
a delay unit configured to randomly adjust a propagation delay time of a first clock signal to generate a second clock signal according to at least one delayed control signal.

17. The clock buffer circuit of claim 16, further comprising:
a delay controller configured to generate the at least one delayed control signal according to at least one control signal.

18. The clock buffer circuit of claim 17, wherein the delay controller comprises:
a random number generation unit configured to generate a pseudo random number by using a linear feedback shift register (LFSR) according to an internal clock signal and the at least one control signal and configured to output the at least one delayed control signal according to the pseudo random number and the at least one control signal.

19. The clock buffer circuit of claim 18, wherein the random number generation unit comprises:
first to fourth flip flops connected in series;
an inverter configured to invert an output of the third flip flop;
an XOR gate configured to perform an XOR operation on the inverted output of the third flip flop and an output of the fourth flip flop;
a first control logic configured to receive an output of the XOR gate and input the output of the XOR gate to the first flip flop according to the at least one control signal; and
a second control logic configured to input the internal clock signal to each of the first to fourth flip flops according to the at least one control signal.

20. The clock buffer circuit of claim 16, wherein the delay unit comprises:
a first delayer configured to delay the first clock signal;
a second delayer configured to delay the first clock signal according to the delayed first clock signal; and
a third delayer for delaying the first clock signal according to the at least one delayed control signal,
wherein the first to third delayers are connected in parallel, and
one of outputs of the first to third delayers is randomly output as the second clock signal according to a propagation delay time of each of the first to third delayers.
